(19) United States
(12) Patent Application Publication
(10) Pub. No.: US 2021/0032753 A1
(43) Pub. Date: Feb. 4, 2021

(54) METHODS AND APPARATUS FOR DUAL CHANNEL SHOWERHEADS

(71) Applicant: APPLIED MATERIALS, INC., Santa Clara, CA (US)

(72) Inventors: Jallepally RAVI, San Ramon, CA (US); Dien-Yeh WU, San Jose, CA (US); Pingyan LEI, San Jose, CA (US); Manjunatha P. KOPPA, Bengaluru (IN); Vinod Konda PURATHE, Bangalore (IN); Takashi KURATOMI, Campbell, CA (US); Mei CHANG, Saratoga, CA (US); Xiaoxiong YUAN, San Jose, CA (US)

(21) Appl. No.: 16/934,343

(22) Filed: Jul. 21, 2020

Related U.S. Application Data
(60) Provisional application No. 62/880,218, filed on Jul. 30, 2019.

(51) Int. Cl. C23C 16/455; H01J 37/32

(52) U.S. Cl. CPC C23C 16/45565; H01J 37/32082; H01J 37/3244; C23C 16/45574

(57) ABSTRACT

Methods and apparatus for gas distribution in a process chamber leverage dual electrodes to provide RF power and an RF ground return in a single showerhead. In some embodiments, the apparatus includes a showerhead composed of a non-metallic material with a first gas channel and a second gas channel, the first gas channel and the second gas channel being independent of each other, and the first gas channel including a plurality of through holes from a top surface of the showerhead to a bottom surface of the showerhead and the second gas channel including a plurality of holes on the bottom surface of the showerhead connected to one or more gas inlets on a side of the showerhead, a first electrode embedded in the showerhead near a top surface of the showerhead, and a second electrode embedded in the showerhead near a bottom surface of the showerhead.

### CROSS-REFERENCE TO RELATED APPLICATIONS

This application claims benefit of U.S. provisional patent application Ser. No. 62/880,218, filed Jul. 30, 2019 which is herein incorporated by reference in its entirety.

### FIELD

Embodiments of the present principles generally relate to semiconductor processing.

### BACKGROUND

Semiconductor substrate processing systems generally include a process chamber having a pedestal for supporting a substrate, such as a semiconductor substrate, within the chamber proximate a processing zone. The chamber forms a vacuum enclosure defining, in part, the processing zone for performing certain processes upon the substrate. In some processes, plasma may be used for the deposition of materials or etching of materials. The plasma produces a harsh environment within the process chamber. Conventional showerheads utilized in process chambers are composed of a metal-based material and include a gas delivery device that flows gas into the process chamber. The gases are used for various processing purposes such as deposition of a material onto a substrate placed in the process chamber. The delivered gas parameters such as pressure, temperature, and velocity impact the processing of the substrate in the chamber. The inventors have found that showerheads composed of metal-based material can react with some gases used during processing, affecting the quality of the processing.

Thus, the inventors have provided improved methods and apparatus for enhanced gas delivery in a semiconductor process chamber.

### SUMMARY

Methods and apparatus for enhanced gas delivery in a semiconductor process chamber are provided herein.

In some embodiments, an apparatus for gas distribution in a process chamber may comprise a showerhead composed of a non-metallic material with a first gas channel and a second gas channel, wherein the first gas channel and the second gas channel are independent of each other; a first electrode embedded in the showerhead near a top surface of the showerhead, and a second electrode embedded in the showerhead near a bottom surface of the showerhead.

In some embodiments, the apparatus may further include wherein the showerhead is comprised of a ceramic material, wherein the ceramic material is aluminum nitride or aluminum oxide, wherein the first electrode is configured to provide a radio frequency (RF) ground return path when installed in the process chamber, wherein the second electrode is configured to provide radio frequency (RF) power when installed in the process chamber, wherein at least one channel of the first gas channel extends from a first opening in the top surface of the showerhead and through the showerhead to a second opening at the bottom surface of the showerhead, wherein the first opening and the second opening are different sizes, wherein at least one channel of the second gas channel extends from a gas inlet on a side of the showerhead to at least one third opening at the bottom surface of the showerhead, wherein the showerhead is a single, unitary piece composed of multiple layers of ceramic material bonded together, and/or wherein the showerhead has a plurality of through holes from the top surface of the showerhead to the bottom surface of the showerhead and a plurality of holes on the bottom surface of the showerhead connected to one or more inlets on a side of the showerhead.

In some embodiments, an apparatus for gas distribution in a process chamber may comprise a showerhead composed of a non-metallic material with a first gas channel and a second gas channel, wherein the first gas channel and the second gas channel are independent of each other, and wherein the first gas channel includes a plurality of through holes from a top surface of the showerhead to a bottom surface of the showerhead and the second gas channel includes a plurality of holes on the bottom surface of the showerhead connected to one or more gas inlets on a side of the showerhead, a first electrode embedded in the showerhead near the top surface of the showerhead, and a second electrode embedded in the showerhead near the bottom surface of the showerhead.

In some embodiments, the apparatus may further include wherein the showerhead is comprised of a ceramic material, wherein the ceramic material is aluminum nitride or aluminum oxide, wherein the first electrode is configured to provide a radio frequency (RF) ground return path when installed in the process chamber, wherein the second electrode is configured to provide radio frequency (RF) power when installed in the process chamber, wherein at least one hole of the plurality of through holes of the first gas channel has a first opening in the top surface of the showerhead and a second opening at the bottom surface of the showerhead and wherein the first opening and the second opening are different sizes, and/or wherein the showerhead is a single, unitary piece composed of multiple layers of ceramic material bonded together.

In some embodiments, a system for processing substrates may comprise a process chamber with an inner process volume; a showerhead configured to divide the inner process volume into an upper process volume and a lower process volume, wherein the showerhead has a first gas channel and a second gas channel that are independent of each other, and wherein the first gas channel is configured to fluidly couple the upper process volume to the lower process volume and the second gas channel is configured to fluidly couple at least one external gas to the lower process volume; a first electrode embedded in the showerhead near a top surface of the showerhead, wherein the first electrode is configured to provide a radio frequency (RF) ground return for plasma generation in the upper process volume; and a second electrode embedded in the showerhead near a bottom surface of the showerhead, wherein the second electrode is configured to provide RF power for plasma generation in the lower process volume.

In some embodiments, the system may further include wherein the showerhead composed of a ceramic material and/or wherein the showerhead is composed of a single, unitary piece comprising multiple layers of ceramic material bonded together.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a cross-sectional view of a process chamber in accordance with some embodiments of the present principles.

FIG. 2 is a cross-sectional view of an intermediate showerhead assembly in accordance with some embodiments of the present principles.

FIG. 3 is a cross-sectional view of an intermediate showerhead assembly in accordance with some embodiments of the present principles.

FIG. 4A is a cross-sectional view of a lower portion of an intermediate showerhead assembly in accordance with some embodiments of the present principles.

FIG. 4B is a cross-sectional view of an upper portion of an intermediate showerhead assembly in accordance with some embodiments of the present principles.

FIG. 5 is an isometric view of layers of an intermediate showerhead assembly in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus provide enhanced gas delivery for plasma processes. In some embodiments, an intermediate showerhead assembly for installation between an upper showerhead and a substrate support in a process chamber provides a dual channel gas delivery system that is impervious to harsh gas environments. The intermediate showerhead assembly may be composed of a non-metallic material such as a ceramic material including but not limited to aluminum nitride or aluminum oxide which is compatible with radicals and gasses based on chlorine, fluorine, hydrogen, nitrogen, silane, and other aggressive chemistries that are typically used in process chambers at high temperatures (above approximately 300 degrees Celsius). The intermediate showerhead assembly provides a dual channel gas delivery showerhead with the capability to strike radio frequency (RF) plasma above the intermediate showerhead assembly as well as below the intermediate showerhead assembly. The intermediate showerhead assembly has an embedded RF mesh electrode near the top side and an embedded RF mesh electrode near the bottom side of the intermediate showerhead assembly.

The inventors have found that for some processes to be accomplished a dual channel gas delivery method should be utilized. The intermediate showerhead assembly provides the compatible material, dual channel gas delivery, and provides the capability to strike plasma above and below the intermediate showerhead assembly. The ability to form plasma above and below the intermediate showerhead assembly enables a remote plasma condition (above the intermediate showerhead assembly) as well as a direct plasma condition (below the intermediate showerhead assembly) based on the process requirement. The advantage of having remote plasma capability in a process chamber is that the plasma species are easier to control. With remote plasma, both ions and radicals are produced. The ions are very directional and are mostly filtered by the intermediate showerhead assembly and stay within the remote plasma (above the intermediate showerhead assembly). The radicals can diffuse and are not directional, easily passing through the intermediate showerhead assembly towards the substrate. In some processes, the radicals are used to react with other elements to create a desired effect on the substrate. The remote plasma allows precise control over the processes such as, for example, chemical vapor deposition (CVD) titanium silicide processes and the like.

In some embodiments, the intermediate showerhead assembly may operate at high temperatures (above approximately 300 degrees Celsius) while delivering gases through dual channels and support remote and direct plasma processes for deposition processes. The inventors have found that the intermediate showerhead assembly provides a solution to a unique process which has many elements of complexity including material, RF, high temperature, and gas delivery compatibility issues. The inventors have also found that ceramic materials such as, for example, aluminum nitride, aluminum oxide (Al₂O₃, alumina), yttrium oxide (Y₂O₃), and silicon carbide (SiC) may be non-reactive with silane gas at high temperatures. The inventors have also found that formation of the intermediate showerhead assembly is a complex procedure that may be simplified by constructing the intermediate showerhead assembly as two separate pieces that are then bonded together to form a single, unitary piece or layer by layer bonding to form the entire piece. Each piece has an embedded RF mesh such that the single, unitary piece has an upper embedded electrode for supporting remote plasma and a lower embedded electrode to support direct plasma (relative to the substrate support).

With the dual gas delivery channels, dual electrodes for remote and direct plasma capability, and composed of a material impervious to hazardous chemistries, the intermediate showerhead assembly may allow for more complex processes to be performed. The advantage of having separate dual channels in the intermediate showerhead assembly is that harsh chemistries may be transferred to the substrate without intermixing with gases in the other channel. For example, the dual channels allow for deposition of films that may help to increase production throughput. When titanium is deposited on silicon, the process consumes the silicon and reduces the electrical benefits gained by using the silicon. By introducing silane into the process, titanium silicide can be formed to stop the consumption of silicon. The intermediate showerhead assembly uses a non-metallic material such as a ceramic composition which is impervious to harsh chemistries such as silane, and with the dual gas delivery channels, allows the silane to be used in processes without mixing with gases from the other channel. The intermediate showerhead assembly provides unique and highly advantageous features that allow previously complicated processes to be performed in a single process chamber, increasing throughput and decreasing costs.

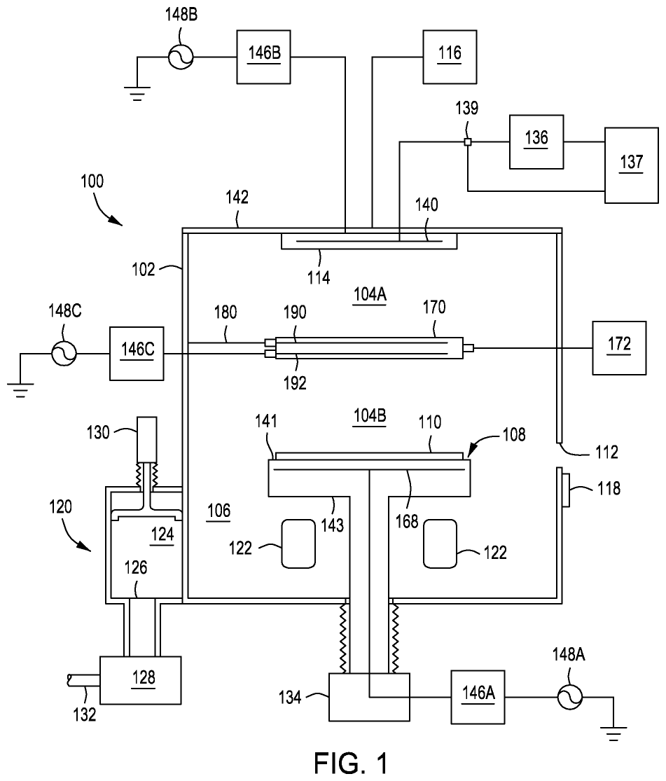

FIG. 1 depicts a process chamber 100 suitable for use in connection with an intermediate showerhead assembly 170 in accordance with some embodiments. The placement and illustrated connections of the intermediate showerhead assembly 170 in the process chamber 100 is strictly exemplary and is not meant to limit placement of, connections, or type of chamber use in any fashion. Exemplary process chambers may include process chambers, available from Applied Materials, Inc. of Santa Clara, Calif. Other suitable chambers include any chambers that use gas delivery apparatus to perform substrate fabrication processes. In some embodiments, the process chamber 100 generally comprises a chamber body 102 defining an upper processing volume 104A, a lower processing volume 104B, and an exhaust volume 106. The upper processing volume 104A may be defined, for example, between an upper showerhead assembly 114 near a ceiling 142 of the process chamber 100 and an intermediate showerhead assembly 170 disposed within the process chamber 100. The lower processing volume 104B may be defined, for example, between a substrate support 108 disposed within the process chamber 100 for supporting a substrate 110 thereupon during processing and the intermediate showerhead assembly 170. The exhaust volume 106 may be defined, for example, between the substrate support 108 and a bottom of the process chamber 100.

The substrate support 108 generally comprises a body 143 having a substrate support surface 141 for supporting a substrate 110 thereon. In some embodiments, the substrate support 108 may include an apparatus that retains or supports the substrate 110 on the surface of the substrate support 108, such as an electrostatic chuck, a vacuum chuck, a substrate retaining clamp, or the like (not shown). In some embodiments, the substrate support 108 may include a radio frequency (RF) bias electrode 168. The RF bias electrode 168 may be coupled to one or more RF bias power sources through one or more respective matching networks (one RF bias power source 148A and one matching network 146A shown in FIG. 1). The one or more bias power sources may be capable of producing up to 6000 W at a frequency of approximately 350 kHz, approximately 2 MHz, approximately 13.56 MHz, or approximately 60 MHz. In some embodiments, two bias power sources may be provided for coupling RF power through respective matching networks to the RF bias electrode at a frequency of approximately 2 MHz and approximately 13.56 MHz. In some embodiments, three bias power sources may be provided for coupling RF power through respective matching networks to the RF bias electrode at a frequency of approximately 2 MHz, approximately 13.56 MHz, and approximately 60 MHz. The at least one bias power source may provide either continuous or pulsed power. In some embodiments, the bias power source may be a DC or pulsed DC source.

In some embodiments, the substrate support 108 may include one or more mechanisms for controlling the temperature of the substrate support surface 141 and the substrate 110 disposed thereon. For example, one or more channels (not shown) may be provided to define one or more flow paths beneath the substrate support surface to flow a heat transfer medium similar to as described below with respect to the upper showerhead assembly 114. The upper showerhead assembly 114 may be coupled to a gas supply 116 for providing one or more process gases into the upper process volume 104A of the process chamber 100. The intermediate showerhead assembly 170 may be coupled to a gas supply 172 for providing one or more process gases into the lower process volume 1046 of the process chamber. The intermediate showerhead assembly 170 is discussed in detail below. Additional gas inlets may be provided such as nozzles or inlets disposed in the ceiling or on the sidewalls of the process chamber 100 or at other locations suitable for providing gases to the process chamber 100, such as the base of the process chamber 100, the periphery of the substrate support 108, or the like.

In some embodiments, the RF plasma power source 148B and/or the RF plasma power source 148C may be coupled to the process chamber 100 through one or more matching networks 146B, 146C for providing power for processing. In some embodiments, the process chamber 100 may utilize capacitively coupled RF power provided to an upper electrode 140 proximate an upper portion of the process chamber 100. The upper electrode 140 may be a conductor in an upper portion of the process chamber 100 or formed, at least in part, by one or more of a ceiling 142, the upper showerhead assembly 114, or the like, fabricated from a suitable conductive material. For example, in some embodiments, one or more RF plasma power sources 148B may be coupled to a conductive portion of the ceiling 142 of the process chamber 100 or to a conductive portion of the upper showerhead assembly 114. The ceiling 142 may be substantially flat, although other types of ceilings, such as dome-shaped ceilings or the like, may also be utilized.

In some embodiments, the intermediate showerhead assembly 170 may have a first electrode 190 embedded near a top surface of the intermediate showerhead assembly that acts as an RF ground return for the one or more RF plasma power sources 148B to support plasma in an upper process volume 104A above the intermediate showerhead assembly 170. The first electrode 190 may be grounded 180 to a wall of the process chamber 100. In some embodiments, a second electrode 192 in the intermediate showerhead assembly 170 may be coupled to RF plasma power source 148B or to another RF plasma power source 148C via matching network 146C to support plasma in the lower process volume 104B. The RF plasma power sources 148B, 148C may be capable of producing up to 6000 W at a frequency of approximately 350 kHz, approximately 13.56 MHz, or higher frequency, such as approximately 27 MHz and/or approximately 60 MHz and/or approximately 162 MHz. Alternatively, the one or more RF plasma power sources 148B may be coupled to inductive coil elements (not shown) disposed proximate the ceiling of the process chamber 100 to form a plasma with inductively coupled RF power.

In some embodiments, the upper process volume 104A and the lower process volume 104B may be fluidly coupled to an exhaust system 120. The exhaust system 120 may facilitate uniform flow of the exhaust gases from the upper process volume 104A and the lower process volume 104B of the process chamber 100. The exhaust system 120 generally includes a pumping plenum 124 and a plurality of conduits (not shown) that couple the pumping plenum 124 to the upper process volume 104A and the lower process volume 104B of the process chamber 100. A conduit has an inlet 122 coupled to the upper process volume 104A and the lower process volume 104B (or, in some embodiments, the exhaust volume 106) and an outlet (not shown) fluidly coupled to the pumping plenum 124. For example, a conduit may have an inlet 122 disposed in a lower region of a sidewall or a floor of the process chamber 100. In some embodiments, the inlets are substantially equidistantly spaced from apart.

A vacuum pump 128 may be coupled to the pumping plenum 124 via a pumping port 126 for pumping out the exhaust gases from the process chamber 100. The vacuum pump 128 may be fluidly coupled to an exhaust outlet 132 for routing the exhaust to appropriate exhaust handling equipment. A valve 130 (such as a gate valve, or the like) may be disposed in the pumping plenum 124 to facilitate control of the flow rate of the exhaust gases in combination with the operation of the vacuum pump 128. Although a z-motion gate valve is shown, any suitable, process compatible valve for controlling the flow of the exhaust may be utilized.

In operation, the substrate 110 may enter the process chamber 100 via an opening 112 in the chamber body 102. The opening 112 may be selectively sealed via a slit valve 118, or other apparatus for selectively providing access to the interior of the chamber through the opening 112. The substrate support 108 may be coupled to a lift apparatus 134 that may control the position of the substrate support 108 between a lower position (as shown) suitable for transferring substrates into and out of the chamber via the opening 112 and a selectable upper position suitable for processing. The process position may be selected to maximize process uniformity for a particular process step. When in an elevated processing position, the substrate support 108 may be disposed above the opening 112 to provide a symmetrical processing region. After the substrate 110 is disposed within the process chamber 100, the chamber may be pumped down to a pressure suitable for forming a plasma and one or more process gases may be introduced into the process chamber 100 via the upper showerhead assembly 114 and/or the intermediate showerhead assembly 170 (and/or other gas inlets). RF power may be provided to strike and maintain a plasma in the upper process volume 104A and/or the lower process volume 104B from the process gases to process the substrate 110. During processing, such as in the above example, the temperature of the upper showerhead assembly 114 may be controlled to provide a more uniform temperature profile across a substrate-facing surface of the upper showerhead assembly 114. A heat transfer medium source 136 may be coupled to the channels to provide the heat transfer medium to the one or more channels. A controller 137 may control the operation of the one or more valves 139 and/or of the heat transfer medium source 136.

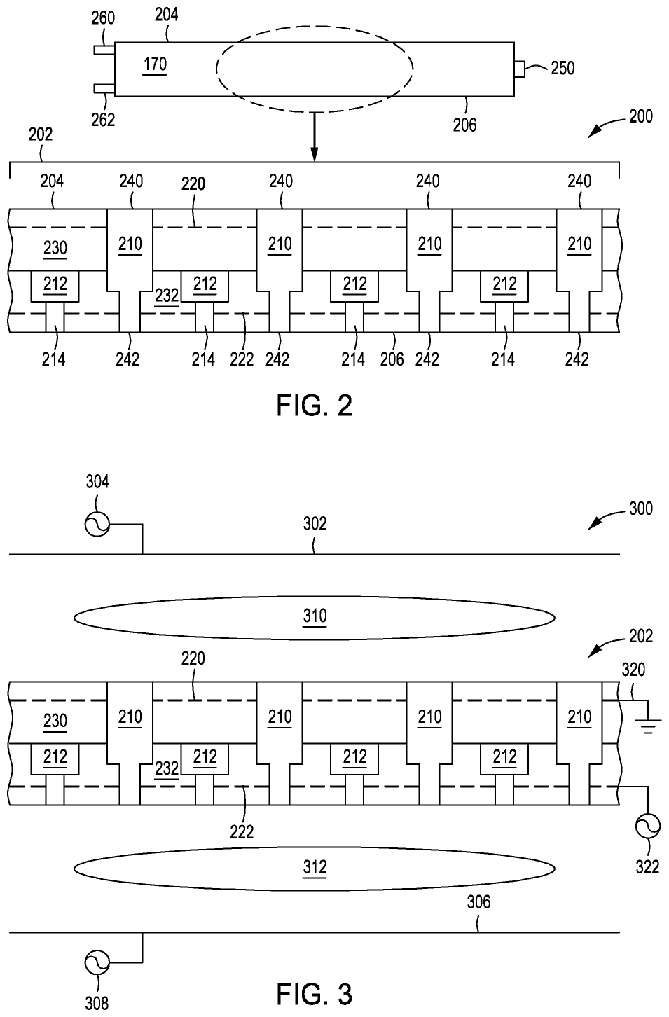

In FIG. 2 is a cross-sectional view 200 of the intermediate showerhead assembly 170 of FIG. 1. A portion 202 of the intermediate showerhead assembly 170 illustrates features embedded in the intermediate showerhead assembly 170. The portion 202 has a top surface 204 and a bottom surface 206. The top surface 204 has first openings 240 that lead into first channels 210. The first openings 240 are opposite the second openings 242 that are on the bottom surface 206. In some embodiments, the first openings 240 may be larger than the second openings 242 (as shown in FIG. 2). In some embodiments, the first openings 240 may be approximately the same size as the second openings 242. In some embodiments, the first channels 210 may have a constant diameter, a diameter that tapers gradually from the first openings 240 to a smaller size at the second openings 242, or a first diameter that is constant for a first portion of the first channels 210 and a second diameter that is constant for a second portion of the first channels 210 but where the second diameter is less than the first diameter (as shown in FIG. 2). In some embodiments, the diameter of the first channels 210 may be widest mid-way between the top surface 204 and the bottom surface 206 and smaller at the first openings 240 and the second openings 242 (e.g., a barrel-like shape). The first channels 210 allow gases in a volume above the intermediate showerhead assembly 170 to pass through to a volume below the intermediate showerhead assembly 170. In some embodiments, the first openings 240 allow radicals (which are generally anisotropic) produced by plasma to pass through the intermediate showerhead assembly 170 while restricting ions (which are generally isotropic) produced by the plasma.

Second channels 212 are embedded into the intermediate showerhead assembly 170 and allow a second gas to flow independently and separately from gases that flow through the first channels 210. The second channels 212, unlike the first channels 210, are interconnected inside the intermediate showerhead assembly 170. In some embodiments, the second channels 212 may have one or more gas inlets 250 on a side of the intermediate showerhead assembly 170 that are configured to accept an external gas source such as gas supply 172 of FIG. 1. The second channels 212 have third openings 214 for releasing a gas towards a surface of a substrate (e.g., substrate 110). The third openings 214 may or may not have a size similar to either of the first openings 240 or the second openings 242. The second channels 212 allow delivery of a gas separate from gases traveling through the first channels 210. In some processes, different gases may react when intermixed, altering the outcome of the processes. The dual channel gas delivery provided by the intermediate showerhead assembly 170 allows for complex gas processes to be performed without unwanted side effects caused by mixing of gas chemistries. The first openings 240, the second openings 242, and the third openings 214 may have an opening with a size of approximately 0.012 (12 mils) to approximately 0.025 inches (25 mils) or larger.

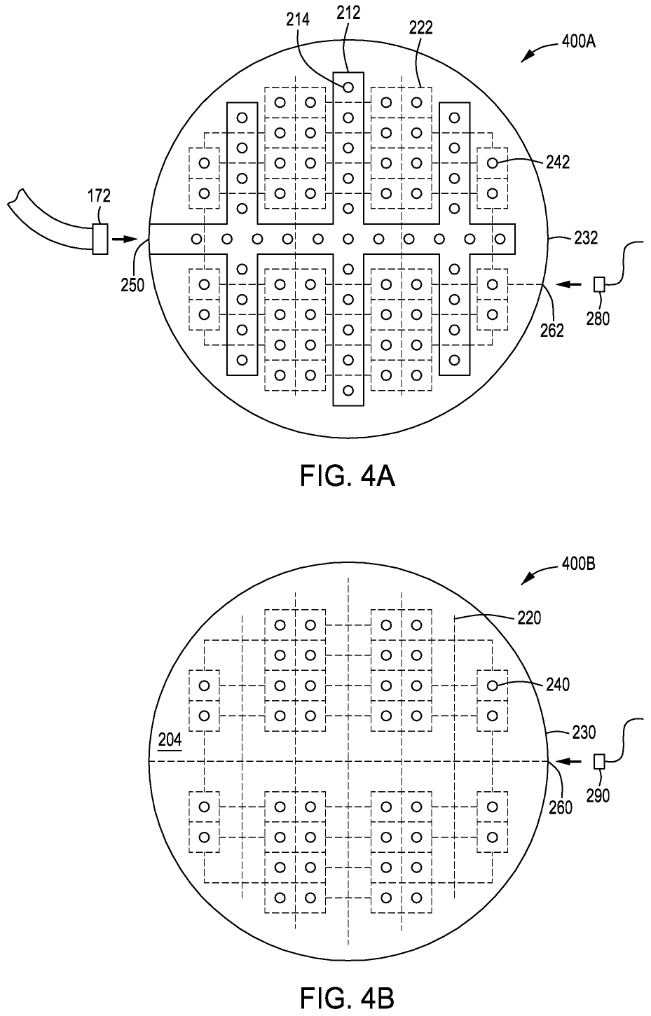

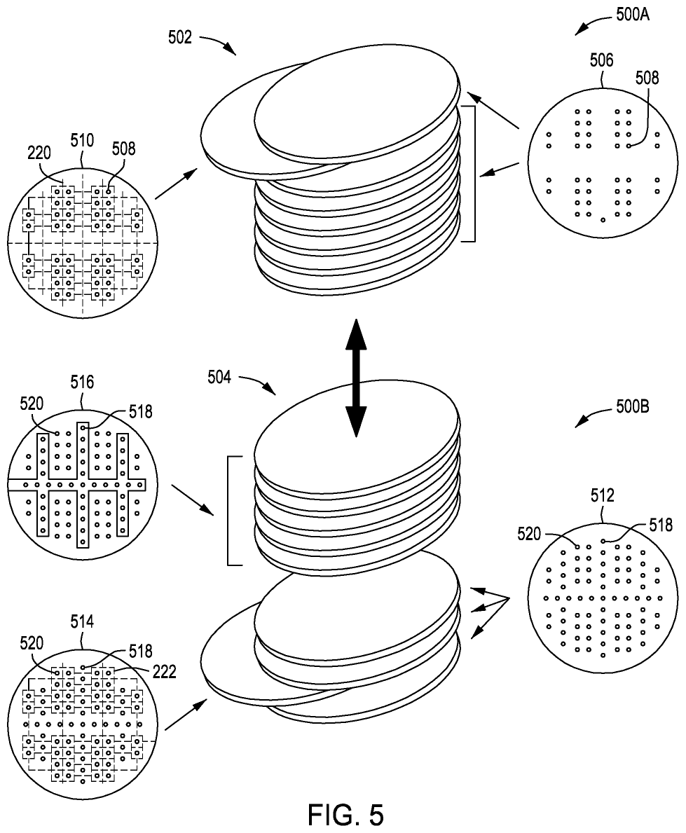

A first electrode 220 is embedded near the top surface 204 of the intermediate showerhead assembly 170. The first electrode 220 is embedded to protect the first electrode 220 from coming into direct contact with harmful gas chemistries in the process chamber. The first electrode 220 is embedded to form a mesh that allows for the first channels 210 to pass through the intermediate showerhead assembly 170 without interfering with the functioning of the first electrode 220 (see, for example, FIG. 4B). In some embodiments, the first electrode 220 may be coupled to a first external electrical connection 260. In some embodiments, the first electrode 220 may be grounded. In some processes, the first electrode 220 may be used as an RF ground return for an electrode positioned above the first electrode 220 such as upper electrode 140 of FIG. 1. The first electrode 220 allows for a remote plasma to be formed above the intermediate showerhead assembly 170 that, subsequently, provides plasma radicals that pass through the first channels 210. The first electrode 220 may provide an RF ground return for RF power forming the plasma above the intermediate showerhead assembly 170.

A second electrode 222 is embedded near the bottom surface 206 of the intermediate showerhead assembly 170. The second electrode 222 is embedded to protect the second electrode 222 from coming into direct contact with harmful gas chemistries in the process chamber. The second electrode 222 is embedded to form a mesh that allows for the first channels 210 to pass through the intermediate showerhead assembly 170 without interfering with the functioning of the second electrode 222 (see, for example, FIG. 4A). The mesh also allows for the third openings 214 of the second channels 212 to reach the bottom surface 206 of the intermediate showerhead assembly 170. In some embodiments, the second electrode 222 may be coupled to a second external electrical connection 262. In some embodiments, the second electrode 222 may provide RF power into the process chamber. In some processes, the second electrode 222 may be used an RF power source with an RF ground return provided by a bias electrode in the substrate support 108 such as the RF bias electrode 168 of FIG. 1. The second electrode 222 allows for a direct plasma to be formed below the intermediate showerhead assembly 170. The second electrode 222 may provide RF power from approximately 50 watts to approximately 6000 watts.

In some embodiments, the intermediate showerhead assembly 170 may be formed in an upper portion 230 and a lower portion 232. The upper portion 230 and the lower portion 232 are then bonded together such that the first channels 210 and the second channels 212 remain vacuum tight and gas leak tight to prevent gas intermixing between a gas in the first channels 210 and a gas in the second channels 212. By constructing each part separately and then combining, the second channels 212 can be formed such that the upper portion 230 provides a ceiling for the second channels 212. See FIGS. 4A, 4B, and 5 for further details on some embodiments for forming the intermediate showerhead assembly 170.

FIG. 3 is a cross-sectional view 300 of the portion 202 of the intermediate showerhead assembly 170 interacting with an upper external electrode 302 connected to an RF power supply 304 and a lower external electrode 306 connected to a bias power supply 308. In the example, the RF power supply 304 provides RF power to the upper external electrode 302 to form remote plasma 310 in conjunction with the first electrode 220 of the intermediate showerhead assembly 170 which acts as an RF ground return 320 for the RF power supply 304. Typically, the lower external electrode 306 is powered by the bias power supply 308. However, the lower external electrode 306 may also function as an RF ground return. In a traditional system, the lower external electrode 306 would function as an RF ground return for the upper external electrode 302 when supplied with power from RF power supply 304. With the intermediate showerhead assembly 170, the second electrode 222 provides power from an external RF power supply 322 and forms direct plasma 312 below the intermediate showerhead assembly 170 with the lower external electrode 306 acting as an RF ground return. The first electrode 220 and the second electrode 222 allow the intermediate showerhead assembly 170 to form both remote plasma and direct plasma during processing of a substrate.

FIG. 4A is a view 400A from a top down perspective of the lower portion 232 of the intermediate showerhead assembly 170. The hole spacing, hole pattern, mesh spacing, mesh pattern, second channel size, second channel spacing, and second channel pattern are meant to be exemplary and not to limit any parameters thereof. The lower portion 232 includes the second channels 212 with third openings 214. The second channels 212 may one or more gas inlets 250 connected to an external gas supply such as gas supply 172 of FIG. 1. The second electrode 222 may connected to a second external electrical connection 262 such as RF power supply connector 280. In some embodiments, the second electrode 222 is formed below the second channels 212 and as such is indicated as dashed lines. The second channels 212 include the third openings 214 inside of the second channels 212. The lower portion of the first channels 210 including second openings 242 are also formed in the lower portion 232.

FIG. 4B is a view 400B from a top down perspective of the upper portion 230 of the intermediate showerhead assembly 170. The hole spacing, hole pattern, mesh spacing, and mesh pattern are meant to be exemplary and not to limit any parameters thereof. The upper portion 230 includes the first channels 210 with first openings 240. The first electrode 220 may connected to a first external electrical connection 260 such as RF ground connector 290. The RF ground connection may also be supplied by a direct contact of the intermediate showerhead assembly 170 to a wall of the process chamber 100. The first electrode 220 is formed below the top surface 204 of the intermediate showerhead assembly 170 and as such is indicated as dashed lines. The upper portion 230 includes spacings between the first openings 240 to allow for the second channels 212 of the lower portion 232.

In some embodiments, due to the difficulties involved with forming ceramic bodies with small holes, electrodes, and cavities for the gas channels, the intermediate showerhead assembly 170 may be formed as a series of laminated or bonded ceramic layers. The advantage of constructing the intermediate showerhead assembly 170 as laminated layers (ceramic layers bonded together into a single piece) is that the size of the holes may be made extremely small in each layer and an electrode or mesh is easier to introduce and locate within the intermediate showerhead assembly 170. The first openings 240, the second openings 241, and/or the third openings 214 may have an opening with a size as small as approximately 0.015 (15 mils) or larger that are formed in the ceramic layers. The layout of the mesh/electrode is also easier to control and the location of the electrode layer may be easily adjusted within the stack of ceramic layers.

In FIG. 5, a first set of layers 502 for the upper portion 230 is illustrated in isometric view 500A. A second set of layers 504 for the lower portion 232 is illustrated in isometric view 500B. In some embodiments, each layer is approximately 1 mm in thickness. In some embodiments, the first set of layers 502 includes eight layers and the second set of layers 504 includes eight layers. In some embodiments, the number of layers for the first set of layers 502 may be any number and the second set of layers 504 may be any number. In some embodiments, the intermediate showerhead assembly 170 has a thickness of approximately 16 mm (for 16-layer stack). In some embodiments, the first set of layers 502 is formed starting at the bottom by bonding together six layers of a first type layer 506 that includes holes 508 to form an upper portion of the first channels 210. A second type layer 510 with holes 508 to form the upper portion of the first channels 210 and with a first electrode 220 embedded in the second type layer 510 is bonded to the top of the six layers. Another first type layer 506 is then bonded to the top of the seven layers to form the upper portion 230 of the intermediate showerhead assembly 170. In some embodiments, the number of the first type layer 506 and the order of the first type layer 506 in respect to the second type layer 510 may be different from the example illustrated in FIG. 5. For example, a top of the first set of layers 502 may have two or more first type layers 506 on top of the second type layer 510 and the like.

In some embodiments, the second set of layers 504 is formed starting at the bottom with a third type layer 512. The third type layer 512 has holes 518 for the third openings 214 and holes 520 for forming the lower portion of the first channels 210. A fourth layer type 514 is then bonded to the third type layer 512. The fourth layer type 514 has holes 518 for the third openings 214 and holes 520 for forming the lower portion of the first channels 210. Two more layers of the third type layer 512 are then bonded to the fourth layer type 514. Four more layers of a fifth type layer 516 are then bonded to the other layers completing the second set of layers to form the lower portion 232 of the intermediate showerhead assembly 170. The fifth layer type 516 has holes 518 for the third openings 214, holes 520 for forming the lower portion of the first channels 210, and channels to form the second channels 212. In some embodiments, the number of the third type layers 512 and the number of fifth type layers 516 may differ and the placement of the fourth layer type 514 in respect to the bottom of the second set of layers 504 may be different from the example illustrated in FIG. 5. For example, a third layer from a bottom of the second set of layers 504 may be a fourth layer type 514 with more or less third type layers 512 and fifth type layers 516 and the like. Once the first set of layers 502 is completed and the second set of layers 504 is completed, the upper portion 230 of the intermediate showerhead assembly 170 and the lower portion 232 of the intermediate showerhead assembly 170 are then bonded together in a vacuum tight and gas tight manner to form the intermediate showerhead assembly 170. In some embodiments, the intermediate showerhead assembly 170 may be constructed layer by layer to form a complete intermediate showerhead assembly 170 rather than forming an upper portion 230 and a lower portion 232 that is then bonded together.

While the foregoing is directed to embodiments of the present principles, other and further embodiments of the principles may be devised without departing from the basic scope thereof.

1. An apparatus for gas distribution in a process chamber, comprising:
a showerhead composed of a non-metallic material with a first gas channel and a second gas channel, wherein the first gas channel and the second gas channel are independent of each other;
a first electrode embedded in the showerhead near a top surface of the showerhead; and
a second electrode embedded in the showerhead near a bottom surface of the showerhead.

2. The apparatus of claim 1, wherein the showerhead is comprised of a ceramic material.

3. The apparatus of claim 2, wherein the ceramic material is aluminum nitride or aluminum oxide.

4. The apparatus of claim 1, wherein the first electrode is configured to provide a radio frequency (RF) ground return path when installed in the process chamber.

5. The apparatus of claim 1, wherein the second electrode is configured to provide radio frequency (RF) power when installed in the process chamber.

6. The apparatus of claim 1, wherein at least one channel of the first gas channel extends from a first opening in the top surface of the showerhead and through the showerhead to a second opening at the bottom surface of the showerhead.

7. The apparatus of claim 6, wherein the first opening and the second opening are different sizes.

8. The apparatus of claim 1, wherein at least one channel of the second gas channel extends from a gas inlet on a side of the showerhead to at least one third opening at the bottom surface of the showerhead.

9. The apparatus of claim 1, wherein the showerhead is a single, unitary piece composed of multiple layers of ceramic material bonded together.

10. The apparatus of claim 1, wherein the showerhead has a plurality of through holes from the top surface of the showerhead to the bottom surface of the showerhead and a plurality of holes on the bottom surface of the showerhead connected to one or more inlets on a side of the showerhead.

11. An apparatus for gas distribution in a process chamber, comprising:
a showerhead composed of a non-metallic material with a first gas channel and a second gas channel, wherein the first gas channel and the second gas channel are independent of each other, and wherein the first gas channel includes a plurality of through holes from a top surface of the showerhead to a bottom surface of the showerhead and the second gas channel includes a plurality of holes on the bottom surface of the showerhead connected to one or more gas inlets on a side of the showerhead;
a first electrode embedded in the showerhead near the top surface of the showerhead; and
a second electrode embedded in the showerhead near the bottom surface of the showerhead.

12. The apparatus of claim 11, wherein the showerhead is comprised of a ceramic material.

13. The apparatus of claim 12, wherein the ceramic material is aluminum nitride or aluminum oxide.

14. The apparatus of claim 11, wherein the first electrode is configured to provide a radio frequency (RF) ground return path when installed in the process chamber.

15. The apparatus of claim 11, wherein the second electrode is configured to provide radio frequency (RF) power when installed in the process chamber.

16. The apparatus of claim 11, wherein at least one hole of the plurality of through holes of the first gas channel has a first opening in the top surface of the showerhead and a second opening at the bottom surface of the showerhead and wherein the first opening and the second opening are different sizes.

17. The apparatus of claim 11, wherein the showerhead is a single, unitary piece composed of multiple layers of ceramic material bonded together.

18. A system for processing substrates, comprising:
a process chamber with an inner process volume;
a showerhead configured to divide the inner process volume into an upper process volume and a lower process volume, wherein the showerhead has a first gas channel and a second gas channel that are independent of each other, and wherein the first gas channel is configured to fluidly couple the upper process volume to the lower process volume and the second gas channel is configured to fluidly couple at least one external gas to the lower process volume;
a first electrode embedded in the showerhead near a top surface of the showerhead, wherein the first electrode is configured to provide a radio frequency (RF) ground return for plasma generation in the upper process volume; and
a second electrode embedded in the showerhead near a bottom surface of the showerhead, wherein the second electrode is configured to provide RF power for plasma generation in the lower process volume.

19. The system of claim 18, wherein the showerhead composed of a ceramic material.

20. The system of claim 19, wherein the showerhead is composed of a single, unitary piece comprising multiple layers of ceramic material bonded together.
